(19) United States
(12) Patent Application Publication
(10) Pub. No.: US 2026/0020204 A1
(43) Pub. Date: Jan. 15, 2026

(54) HOUSING ASSEMBLY COMPRISING A SHIELD AGAINST ELECTROMAGNETIC INTERFERENCE

(71) Applicant: Schaeffler Technologies AG & Co. KG, Herzogenaurach (DE)

(72) Inventors: Loïc ROQUES, Toulouse (FR); Nicolas TERRASSON, Toulouse (FR); Eric GENDRE, Toulouse (FR)

(21) Appl. No.: 19/223,802

(22) Filed: May 30, 2025

(30) Foreign Application Priority Data
Jul. 12, 2024 (FR) 2407632

(51) Int. Cl. H05K 9/00

(52) U.S. Cl. CPC H05K 9/0007

(57) ABSTRACT

The present invention relates to a housing assembly (10) comprising side walls (14, 16, 18, 20) and at least one transverse wall (24), said walls (14, 16, 18, 20, 24) being configured to define a recess (28) capable of receiving at least one electronic board (30) provided with electronic components (36), characterized in that it comprises at least one series (S1, S2) of metal pins (38) that are arranged in the thickness of at least one of the walls (14, 16, 18, 20, 24) so as to protect at least one zone (Z1, Z4) of the electronic board (30) or at least one component (36) of the electronic board (30) against electromagnetic interference.

### TECHNICAL FIELD OF THE INVENTION

The present invention relates to a housing assembly.

The invention relates more particularly to a housing assembly suitable for containing an electronic board provided with electronic components.

### TECHNICAL BACKGROUND

It is known practice, in particular in the field of automotive electronics, to place electronic boards in plastic housings. However, the electronic components placed on these boards can be subject to electromagnetic interference or generate electromagnetic fields that can interfere with other electronic components.

The present patent application aims to propose a solution for protecting against electromagnetic interference.

### SUMMARY OF THE INVENTION

The invention proposes a housing assembly comprising side walls and at least one transverse wall, said walls being configured to define a recess capable of receiving at least one electronic board provided with electronic components, characterized in that it comprises at least one series of metal pins that are arranged in the thickness of at least one of the walls so as to protect at least one zone of the electronic board or at least one component of the electronic board against electromagnetic interference.

The proposed technical solution makes it possible to create a shield against the electromagnetic waves produced by the electronic components. The metal pins form a screen or guard against the magnetic field. This makes it possible to simultaneously protect the electronic components contained in the housing against electromagnetic waves originating from outside the housing, and protect the environment surrounding the housing against electromagnetic waves emitted by said electronic components.

According to other features of the housing assembly:
the metal pins of each series are arranged parallel to each other;
the housing assembly comprises at least a first series of metal pins arranged in the thickness of a first side wall, along said first side wall, and a second series of metal pins arranged in the thickness of the transverse wall;
the metal pins of the first series are substantially parallel to the metal pins of the second series;
each metal pin comprises an axial end substantially flush with a surface of the associated wall;
at least one of the electronic components of the electronic board is arranged facing a series of metal pins;
at least some of the metal pins extend protruding relative to the transverse wall toward the inside of the housing so as to form a protective grille on at least one side of an electronic component.

A method is also proposed for manufacturing a housing assembly according to any one of the preceding features, comprising the following steps:
producing a housing made from plastic comprising side walls and at least one transverse wall, said walls being configured to define a recess capable of receiving at least one electronic board provided with electronic components,
producing at least one series of vertical cavities in the thickness of at least one of the walls, said vertical cavities being suitable for receiving an associated series of metal pins by force-fitting,
force-fitting at least one series of metal pins into the vertical cavities,
positioning the electronic board in the recess so that at least one zone of the electronic board or at least one component of the electronic board is protected against electromagnetic interference by the series of metal pins.

According to other features of the method:
during the fitting step, a first and a second series of metal pins are force-fitted, the first series being fitted into the thickness of a side wall and the second series being fitted into the thickness of the transverse wall;
the first and second series are fitted from the same side of the housing.

### BRIEF DESCRIPTION OF THE FIGURES

Further features and advantages of the invention will become apparent on reading the following detailed description, which will be more clearly understood with reference to the appended drawings, in which:

FIG. 1 is an axial cross-sectional view along the plane I-I in FIG. 2, showing a housing assembly produced according to the teachings of the invention and comprising a plate supporting an electronic board provided with electronic components placed in a recess defined by the housing;

FIG. 2 is a bottom view showing the housing of the housing assembly in FIG. 1, without the plate and the electronic board;

FIG. 3 is a cross-sectional view similar to the view in FIG. 1, illustrating a step of the method for manufacturing the housing assembly according to the invention, before the fitting of the metal pins with which it is provided;

FIG. 4 is a view similar to the view in FIG. 1, showing a variant embodiment with elongated metal pins.

### DETAILED DESCRIPTION OF THE INVENTION

For the description of the invention and the understanding of the claims, the vertical, longitudinal and transverse orientations will be adopted non-limitingly, and without limiting reference to the Earth's gravitational field, according to the coordinate system V, L, T indicated in the figures, in which the longitudinal axis L and transverse axis T extend in a horizontal plane. By convention, the longitudinal axis L is oriented from the rear forwards.

In the following description, identical, similar or analogous elements will be denoted by the same reference signs.

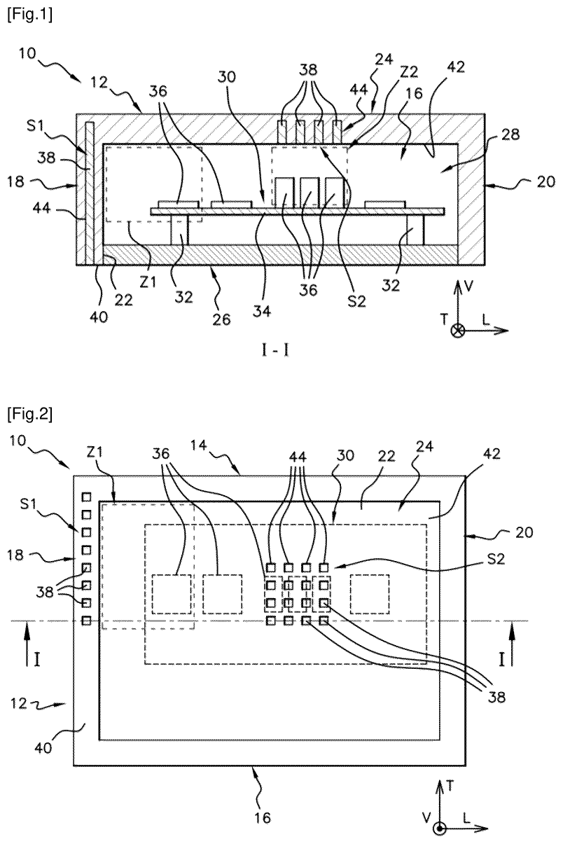

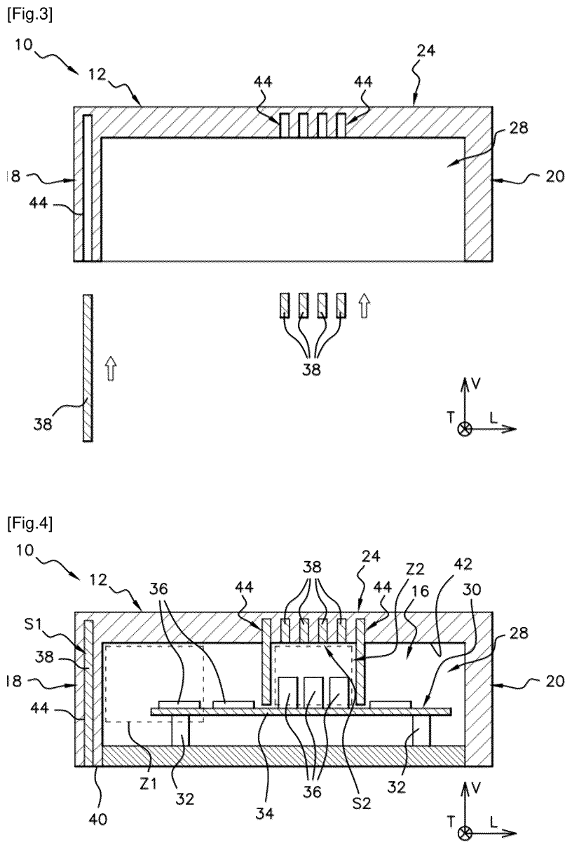

FIG. 1 illustrates a housing assembly 10 comprising a generally parallelepipedal housing 12. Here, the housing 12 comprises two longitudinal side walls 14, 16 and two transverse side walls 18, 20 that define an opening 22 in the lower part of the housing 12. Here, the upper part of the housing 12 is closed by a transverse wall, referred to as the end wall 24, which here extends transversely and is integrally formed with the side walls 14, 16, 18, 20.

Here, the opening 22 is closed by a plate 26 that extends in a transverse plane.

The housing 12 thus forms a recess 28 in which an electronic board 30 is arranged.

According to the embodiment shown, the electronic board 30 is fastened on the inner face of the plate 26 by means of fastening studs 32.

Of course, according to variant embodiments, the electronic board 30 could be arranged and fastened differently.

Here, the electronic board 30 is in the form of a printed circuit board 34 provided with electronic components 36 on at least one of its faces.

Advantageously, the housing 12 comprises a first series S1 of metal pins 38 that are arranged in the thickness of one of the transverse side walls 18, 20, on the left in FIGS. 1 and 2.

These metal pins 38 are for example in the form of vertical rods having a square cross-section. They are preferably force-fitted into the transverse side walls 18, 20, which are provided in advance with suitable vertical cavities 44.

According to the example shown, the first series S1 comprises eight metal pins 38 that are evenly spaced apart by a predetermined distance, for example substantially equal to the transverse cross-sectional dimension of a metal pin 38. Here, the first series S1 is arranged on part of the transverse side wall 18 only.

Here, the housing 12 comprises a second series S2 of metal pins 38 that are arranged in the thickness of the end wall 24. According to the example shown, this second series S2 comprises sixteen metal pins 38 that are evenly spaced apart and form a square pattern.

According to the embodiment shown, all of the pins 38 of the first and second series S1, S2 are vertically oriented, here orthogonally to the electronic board 30. They are therefore parallel to each other.

The positioning of these metal pins 38 is selected in order to protect at least one protected zone Z1, Z2 of the electronic board 30 or at least one electronic component 36 of the electronic board 30 against electromagnetic interference.

According to the embodiment shown, the first series S1 provides protection against electromagnetic interference in a lateral first protected zone Z1 situated on the left-hand side, with reference to FIGS. 1 and 2, as illustrated by the rectangle in dashed lines in FIGS. 1 and 2. In this example, one electronic component 36 is covered by this first protected zone Z1, as it is arranged facing the row of metal pins 38 of the first series S1.

According to the embodiment shown, the second series S2 provides protection against electromagnetic interference in a second protected zone Z2 situated below, as illustrated by the rectangle in dashed lines in FIG. 1. In this example, three electronic components 36 are covered by this second protected zone Z2, as they are placed facing the metal pins 38 of the second series S2.

The metal pins 38 of the first series S1 here have a length slightly less than the height of the transverse side walls 14, 16, which makes it possible to cover a protected zone Z1 extending substantially over the entire height of the housing 12.

The metal pins 38 of the second series S2 here have a length slightly less than the vertical thickness of the end wall 24. They are therefore significantly shorter than the metal pins 38 of the first series S1.

It will be noted that the cross-section of the metal pins 38 could be round or another shape. In addition, the pattern formed by the metal pins 38 of the second series S2 in the end wall 24 could be different, in particular to adapt to the positioning of the electronic components to be protected.

One advantage of the proposed solution is that it can be adapted to different configurations of electronic board 30, without it being necessary to arrange metal pins 38 on all of the walls of the housing 12 or over the entire length of these walls.

Advantageously, the metal pins 38 are force-fitted into the walls of the housing 12, until one axial end is left substantially flush with a surface of the associated wall.

As can be seen in FIG. 2, the lower ends of the metal pins 38 of the first and second series S1, S2 can be seen from below. In FIG. 1, it can be seen that the lower end of the metal pins 38 of the first series S1 is flush with the lower edge 40 of the associated transverse side wall 18 and the lower end of the metal pins 38 of the second series S2 is flush with the inner surface of the 42 of the end wall 24.

A method for manufacturing the housing assembly 10 described above will now be described.

During a first step, the housing 12 is made from plastic by plastic injection molding. During this molding step, the transverse side walls 14, 16 and the end wall 24 can be provided with vertical cavities 44 capable of receiving the metal pins 38. According to one variant embodiment, the vertical cavities 44 can be produced after molding, for example using a drilling tool.

During a second step, the metal pins 38 are force-fitted into the vertical cavities 44.

During a third step, the electronic board 30 is positioned in the recess 28 so that the electronic components 36 that require protection against electromagnetic interference are placed facing the metal pins 38, in the protected zones Z1, Z2.

Advantageously, the openings of all of the vertical cavities 44 are placed on the same side, which facilitates the step of fitting the metal pins 38.

FIG. 4 shows a variant embodiment in which the second series S2 of metal pins 38 comprises elongated metal pins 38 on the perimeter of the second protected zone Z2. These metal pins 38 thus descend until they are close to the printed circuit board 34, from the inner surface 42 of the end wall 24. They therefore protrude from the lower surface 42. They form a shield that surrounds the components 36 and protects them against electromagnetic waves emitted transversely.

### KEY

10: housing assembly
12: housing
14, 16: longitudinal side wall
18, 20: transverse side wall
22: opening
24: end wall
26: plate
28: recess
30: electronic board
32: fastening studs
34: printed circuit board
36: electronic components
38: metal pins
40: lower edge
42: inner surface
44: vertical cavities
S1: first series of metal pins
S2: second series of metal pins
Z1: first protected zone
Z2: second protected zone

1. A housing assembly (10) comprising side walls (14, 16, 18, 20) and at least one transverse wall (24), said walls (14, 16, 18, 20, 24) being configured to define a recess (28) capable of receiving at least one electronic board (30) provided with electronic components (36), characterized in that it comprises at least one series (S1, S2) of metal pins (38) that are arranged in the thickness of at least one of the walls (14, 16, 18, 20, 24) so as to protect at least one zone (Z1, Z4) of the electronic board (30) or at least one component (36) of the electronic board (30) against electromagnetic interference.

2. The housing assembly (10) as claimed in claim 1, characterized in that the metal pins (38) of each series are arranged parallel to each other.

3. The housing assembly (10) as claimed in claim 1, characterized in that it comprises at least a first series (S1) of metal pins (38) arranged in the thickness of a first side wall (18), along said first side wall (18), and a second series (S2) of metal pins (38) arranged in the thickness of the transverse wall (24).

4. The housing assembly (10) as claimed in claim 3, characterized in that the metal pins (38) of the first series (S1) are substantially parallel to the metal pins (38) of the second series (S2).

5. The housing assembly (10) as claimed in claim 1, characterized in that each metal pin (38) comprises one axial end substantially flush with a surface of the associated wall.

6. The housing assembly (10) as claimed in claim 1, characterized in that at least one of the electronic components (36) of the electronic board (30) is arranged facing a series (S1, S2) of metal pins (38).

7. The housing assembly (10) as claimed in claim 1, characterized in that at least some of the metal pins (38) extend protruding relative to the transverse wall (24) toward the inside of the housing (12) so as to form a shield on at least one side of an electronic component (36) of the electronic board (30).

8. A method for manufacturing a housing assembly (10) as claimed in claim 1, comprising the following steps:
producing a plastic housing (12) comprising side walls (14, 16, 18, 20) and at least one transverse wall (24), said walls (14, 16, 18, 20, 24) being configured to define a recess (28) capable of receiving at least one electronic board (30) provided with electronic components (36),
producing at least one series of vertical cavities (44) in the thickness of at least one of the walls (14, 16, 18, 20, 24), said vertical cavities (44) being suitable for receiving an associated series of metal pins (38) by force-fitting,
force-fitting at least one series (S1, S2) of metal pins (38) into the vertical cavities (44),
positioning the electronic board (30) in the recess (28) so that at least one zone (Z1, Z2) of the electronic board (30) or at least one component (36) of the electronic board (30) is protected against electromagnetic interference by the series of metal pins (38).

9. The manufacturing method as claimed in claim 8, characterized in that, during the fitting step, a first and a second series (S1, S2) of metal pins (38) are force-fitted, the first series (S1) being fitted into the thickness of a side wall (18) and the second series (S2) being fitted into the thickness of the transverse wall (24).

10. The manufacturing method as claimed in claim 9, characterized in that the first and second series (S1, S2) are fitted from the same side of the housing (12).
